(19) United States
(12) Patent Application Publication
(10) Pub. No.: US 2014/0027710 A1
(43) Pub. Date: Jan. 30, 2014

(54) QUANTUM DOT AND NANOWIRE SYNTHESIS

(71) Applicants: Feng Liu, Salt Lake City, UT (US); Gerald Stringfellow, Salt Lake City, UT (US); Xiaobin Niu, Salt Lake City, UT (US)

(72) Inventors: Feng Liu, Salt Lake City, UT (US); Gerald Stringfellow, Salt Lake City, UT (US); Xiaobin Niu, Salt Lake City, UT (US)

(73) Assignee: UNIVERSITY OF UTAH RESEARCH FOUNDATION, Salt Lake City, UT (US)

(21) Appl. No.: 13/991,134

(22) PCT Filed: Dec. 3, 2011
(86) PCT No.: PCT/US11/63200

§ 371 Date: Oct. 18, 2013

Related U.S. Application Data
(60) Provisional application No. 61/419,662, filed on Dec. 3, 2010.
(60) Provisional application No. 61/533,651, filed on Sep. 12, 2011.

(51) Int. Cl. H01L 21/02; H01L 33/06; H01L 29/12

(52) U.S. Cl. CPC H01L 21/02601; H01L 29/127; H01L 33/06
USPC 257/13; 438/478; 257/14

(57) ABSTRACT

A self-assembled semiconductor nanostructure includes a core and a shell, wherein one of the core or the shell is rich in a strained component and the other of the core or the shell is rich in an unstrained component, wherein the nanostructure is a quantum dot or a nanowire. A method includes growing a semiconductor alloy structure on a substrate using a growth mode that produces a semiconductor alloy structure having a self-assembled core and shell and allowing the structure to equilibrate such that one of the core or the shell is strained and the other is unstrained. Another method includes growing at least one semiconductor alloy nanostructures on a substrate, wherein the nanostructure comprises a strained component and an unstrained component, and controlling a compositional profile during said growing such that a transition between the strained component and an unstrained component is substantially continuous.

### REFERENCE TO GOVERNMENT RIGHTS

This invention was made with government support under grant number DE-FG02-04ER46148 awarded by the U.S. Department of Energy. The US government has certain rights in this invention.

### TECHNICAL FIELD OF THE INVENTION

The present invention relates generally to the field of nanostructures and methods of making nanostructures. Specifically, the present application relates to strained alloy nanostructures such as semiconductor alloy nanostructures, for example, quantum dots and nanowires.

### CROSS-REFERENCE TO RELATED APPLICATIONS

This application claims the benefit of PCT Application No. PCT/US11/63200, filed Dec. 3, 2011, which is a non-provisional of U.S. Provisional Application No. 61/419,662, filed Dec. 3, 2010, and U.S. Provisional Application No. 61/533,651, filed Sep. 12, 2011, the disclosure of each of these applications is incorporated herein by reference in their entirety.

### BACKGROUND OF THE INVENTION

Formation of heterostructures and junctions in semiconductor alloy quantum dots (QDs) and nanowires (NW s) during epitaxial growth processes is a key strategy for producing optimal nanophotonic and nanoelectronic materials, including high efficiency blue and green light-emitting diodes (LEDs), visible lasers, and high efficiency solar cells. Desirable device functions may be realized by the formation of axial or radial (core-shell) heterostructures in QDs and NWs, as their electronic and optical properties are in part determined by their composition profiles.

A number of methods have been used to fabricate core-shell QDs and NWs. One approach is to specifically grow the cores and shells in two steps by using changes in growth conditions to vary the growth mechanism. Often the cores are first formed using the vapor-liquid-solid (VLS) mechanism, followed by growth of shells on the sides of the cores using higher temperatures or different reactants during epitaxial growth. However, this approach faces challenges for cost-effective device fabrication, because it is time consuming and the conditions are difficult to control.

Accordingly, there exists a need to overcome the challenges faced by current nanostructure growth mechanisms. There is also a need to provide a method for producing QDs and NWs that have controlled structures. There is also a need to provide heterostructures that are produced by controlled growth modes for use in nanophotonic and nanoelectronic applications, such as high efficiency blue and green light-emitting diodes (LEDs), visible lasers, and high efficiency solar cells.

### SUMMARY OF THE INVENTION

An exemplary embodiment relates to the spontaneous formation of self-assembled core-shell structures (e.g., nanostructures) during epitaxial growth.

Another exemplary embodiment relates to a method of controlling the composition profiles of semiconductor alloy nanostructures, including the step of selecting the growth mode, for example at least one of layer-by-layer or faceted growth mode, and allowing the structure to equilibrate to form a core rich in an unstrained component or a core rich in a strained component.

Another exemplary embodiment relates to a structure (e.g., a nanostructure) such as a quantum dot or nanowire, where the structure has a composition profile that includes a core portion that is rich in a strained component and a surface portion that is rich in an unstrained component, or that instead has a core portion that is rich in an unstrained component and a surface portion that is rich in a strained component.

In a specific exemplary embodiment, at least one of a semiconductor quantum dot or nanowire is formed on a substrate by a layer-by-layer growth mode, wherein the quantum dot or nanowire comprises an indium-rich surface portion, and a GaN-rich core portion.

In another specific embodiment, a semiconductor quantum dot or a nanowire is formed on a substrate by a faceted growth mode, wherein the quantum dot or nanowire comprises an indium-rich core portion, for example a V-shaped core, and a GaN-rich surface portion.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features of the invention can be obtained, a more particular description of the invention briefly described above will be rendered by reference to specific example embodiments thereof which are illustrated in the appended drawings. Understanding that these drawings depict only typical implementations of the invention and are not therefore to be considered to be limiting of its scope, the invention will be described and explained with additional specificity and detail through the use of the accompanying drawings.

FIGS. 1a and 1b are models illustrating the composition profiles of cross-sections of prior art nanostructures, with FIG. 1a showing a triangle-shaped quantum dot and FIG. 1b showing a nanowire.

FIG. 2a is a schematic illustration of a Stranski-Krastanov epitaxial growth process of a strained quantum dot.

FIG. 2b is a schematic illustration of a layer-by-layer growth mode of a quantum dot according to an exemplary embodiment.

FIG. 2c illustrates a faceted growth mode of a quantum dot according to another exemplary embodiment.

FIG. 2d is a composition profile of the quantum dot of FIG. 2b with a core that is rich in an unstrained component resulting from the layer-by-layer growth mode.

FIG. 2e is a composition profile of the quantum dot of FIG. 2c with a V-shaped core that is rich in an unstrained component resulting from the faceted growth mode.

FIG. 3a shows a schematic illustration of a VLS growth process of a strained nanowire according to an exemplary embodiment.

FIG. 3b is a schematic illustration of a layer-by-layer growth mode of a nanowire according to an exemplary embodiment.

FIG. 3c is a schematic illustration of a faceted growth mode of a nanowire according to an exemplary embodiment.

FIG. 3d is a composition profile of the nanowire of FIG. 3b with core rich in an unstrained component resulting from the layer-by-layer growth mode.

FIG. 3e is a composition profile of the nanowire of FIG. 3c with a core rich in a strained component resulting from the faceted growth mode.

FIGS. 4a-4c illustrate a triangle shaped GaN core distribution resulting from a layer-by layer growth mode with equilibration achieved in top 4, 7, and 10 surface layers, respectively, according to an exemplary embodiment.

FIGS. 4d-4 f show a V-shaped InN core distribution resulting from the faceted growth mode with equilibration achieved in top 4, 7 and 10 facet layers.

FIG. 5 illustrates a model system of a 2D square lattice.

FIG. 6 is a flow chart of a Metropolis Monte Carlo method combined with a force balance approach for simulating concentration profiles of quantum dots and nanowires of the embodiments.

FIG. 7 shows calculated composition profiles of Ge_{0.3}Si_{0.7} QDs (FIG. 7a-b) and NWs (FIG. 7c-d) grown on Si substrates by the two growth modes of layer-by-layer growth versus faceted growth according to an exemplary embodiment.

### DETAILED DESCRIPTION

As used herein, the terms “strained” and “unstrained” are intended to be understood as relative terms that relate to the degree of lattice mismatch with respect to a neighboring structure (e.g., a substrate on which strained or unstrained components are grown).

Spontaneously-formed nanostructures have been experimentally observed to exhibit a concentration of strained material (hereinafter referred to as a “strained component”) either in the core or the shell of the nanostructure. For example, where a quantum dot (“QD”) is formed that has a generally pyramidal shape, the quantum dot may have either a core or a shell that is rich in a strained component. This is also the case with nanowires (NWs), where the core or shell may be rich in a strained component.

Good control of the composition profiles in self-assembled QDs and NWs is lacking partly because the physical mechanism underlying the self-assembly is unclear. The occurrence of such uncertainty is mainly because these structures are usually grown under non-equilibrium conditions, but current understanding of the assembly mechanism is based mostly on equilibrium theories. Of course, the equilibrium composition profile will depend on the thermodynamics of mixing of the particular alloy, the mismatch of the alloy with the substrate, the shape of the island or wire, and the growth conditions, and in particular will depend on the temperature and the vapor composition. If thermodynamic equilibrium were to be achieved throughout the nanostructure, no core-shell structure would be observed.

The alloy composition profiles in QDs and NWs are expected to be distinctly different from the equilibrium distribution, because bulk diffusion with an energy barrier of a few eVs is negligible at typical growth temperatures. On the other hand, local equilibrium is often established in the near surface region due to the more rapid surface (and sub-surface) diffusion with a much smaller energy barrier of ˜0.5-1.0 eV so that the alloy composition at the surface is expected to reach local thermodynamic equilibrium during growth. Consequently, the kinetic growth mode, which dictates the manner of surface mass transport and alloy mixing near the growth front, becomes a key factor in determining the kinetically limited composition profile.

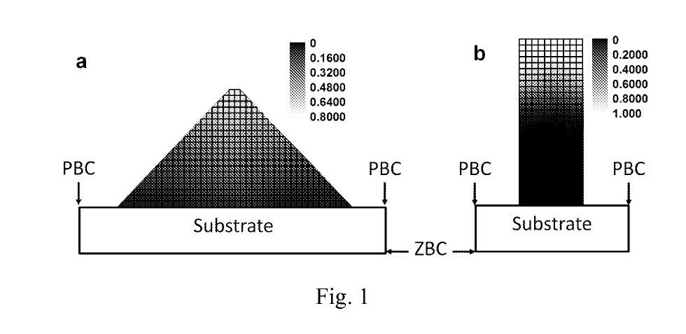

FIG. 1a illustrates an equilibrium composition profile of a faceted In_{0.3}Ga_{0.7}N alloy quantum dot having a generally pyramidal shape. It is well known that strain relaxes nonuniformly in a Stranski-Krastanov (SK) QD, and that most relaxation occurs at the apex and least at the corners of the base of the pyramid. Consequently, as shown in FIG. 1a, the concentration of In (i.e., the strained component) is highest in the apex region of the QD and the concentration of Ga (i.e., the unstrained component) is highest in the corners of the base. The resulting strain effect produces a phase separation within the nanostructure, and the large positive enthalpy of mixing for InGaN further favors phase segregation. In fact, a miscibility gap exists for this alloy. The maximum In concentration at the apex is the thermodynamic equilibrium concentration at the particular temperature and precursor concentrations. Due to strain effects, the In concentration decreases in a generally continuous manner from the apex towards the base and the corners of the base in the QD.

Likewise, the equilibrium In concentration profile in an In_{0.3}Ga_{0.7}N nanowire is illustrated in FIG. 1b. As shown therein, the base regions of the nanowire are constrained to be coherent with the substrate lattice while, because of the large height/width aspect ratio, the top regions are fully relaxed. Consequently, the In atoms tend to segregate towards the top surface with a slight enrichment in the two top corners.

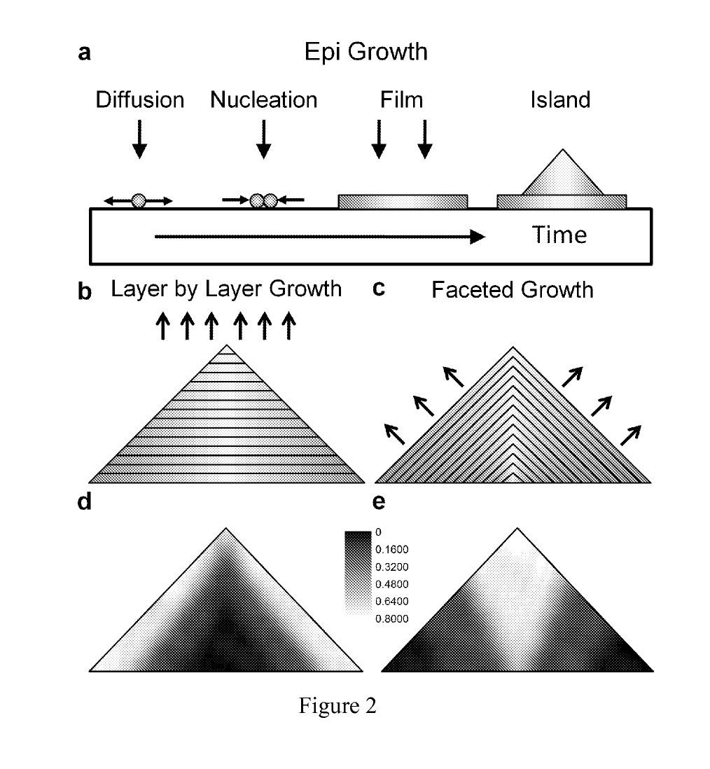

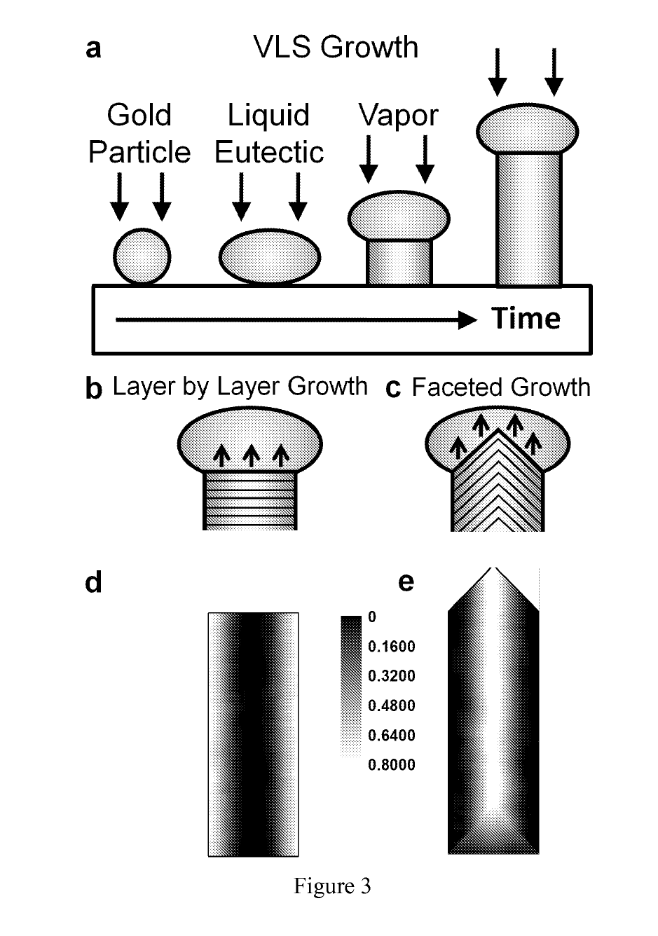

The inventors have discovered a method for controlling the alloy concentration profiles of nanostructures such as strained semiconductor alloy quantum dots and nanowires by controlling the growth mode of such structures. Thus, in contrast to the concentration profiles discussed above with respect to FIGS. 1a and 1b, a layer-by-layer growth mode (in which growth proceeds in the substrate surface normal direction as shown in FIGS. 2b and 3b may be used to produce spontaneously-formed, core-shell nanostructures having a core that is rich in an unstrained component (relative to the substrate) as shown in FIGS. 2d and 3d, respectively; while a faceted growth mode (in which growth proceeds in the island facet normal direction), as illustrated in FIGS. 2c and 3c, may be used to produce nanostructures having a core that is rich in a strained component, as shown in FIGS. 2e and 3e, respectively.

In the layer-by-layer growth mode, strain relaxation results in a “lateral” phase separation, with strained components segregated to the outside (i.e., the outer surface portions of the nanostructures) and unstrained components segregated to middle or core portions of the nanostructures (see, e.g., FIG. 2d, which shows a model of a QD formed using a layer-by-layer growth mode). In faceted growth mode, strain relaxation results in a “vertical” phase separation, with strained components segregated to the top portion (e.g., the apex of the QD as illustrated, for example, in FIG. 2e), such that a V-shaped core is formed; the unstrained components are segregated to the bottom (e.g., edge) portion of the nanostructure.

According to an exemplary embodiment, a method of tuning the growth mode may be used to achieve desirable alloy concentrations in strained QDs and NWs for targeted applications. This can be achieved by adjusting growth parameters (temperature, deposition rate, pressure, concentration, etc.) and/or by surface modification, such as by the application of surfactants.

### SIMULATION EXAMPLES

The inventors have discovered a striking correlation between the composition profile of strained core-shell semiconductor QDs and NWs with the kinetic growth mode. Atomistic-strain-model Monte Carlo (MC) simulations of the epitaxial growth of strained QDs and the VLS growth of strained NWs were performed, in which two different growth modes were considered: layer-by-layer growth and faceted growth, where local compositional equilibrium is reached at the growth front for a range of sub-surface layer thicknesses of from 1 to 10 layers. The calculations show that layer-by-layer growth produces core-shell structures with the core rich in the unstrained (or less strained) component, while faceted growth produces structures with the core rich in the strained component. These growth-mode-controlled alloy composition profiles have been determined to be distinctly different from the equilibrium profiles.

### Example A

### Atomistic Strain Model and Metropolis Monte Carlo Algorithm

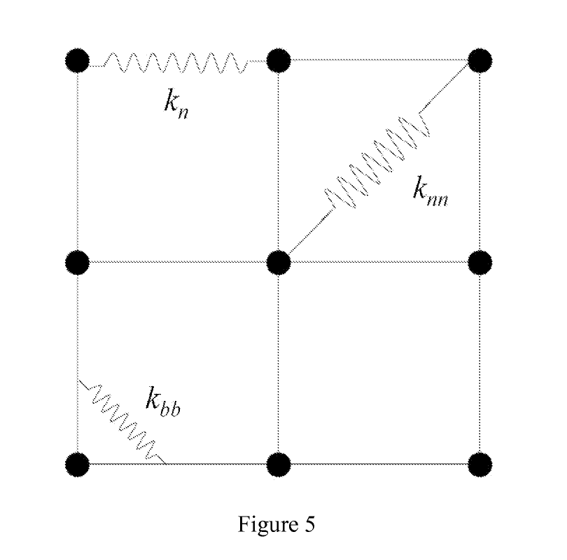

As illustrated in FIG. 1, simulations were carried out in a model system of a 2D square lattice. Characteristics of the model system used in the simulation include: a) dimensionless atomic units; b) periodic boundary conditions laterally; c) zero boundary condition (i.e., no displacement) at the bottom of the substrate; d) free boundary conditions at the QD and NW surfaces; and e) epitaxial boundary at the QD/and NW/substrate. The enthalpy contribution H to the free energy of the entire system was calculated using the atomistic strain model, which assumes harmonic potentials that include nearest-neighbor (NN), next-nearest-neighbor (NNN), and bond-bending (BB) interactions (FIG. 5). The strain energy was calculated as Eₑₗ=kₙ(S²ₓₓ+S²_{yy})+[(Sₓₓ+2S_{xy}+S_{yy})²+(Sₓₓ−2S_{xy}+S_{yy})²]+k_{bb}S²_{xy}, where kn, knn, and kbb are the spring constants for the NN, NNN, and BB springs, and the Sᵢⱼ are the components of the strain tensor. The entropy of mixing was calculated based on the regular solution theory as S=∫ᵥ−k{x(r)ln[x(r)]+(1−x(r))ln[1−x(r)]}, where k is the Boltzmann constant, x(r) is the local concentration (i.e., molar fraction) of a component at position r, and V is a local volume centered at r. Convergence tests were performed with respect to the size of V, for which the entropy is found to be converged at a up to the 10th nearest neighbor. The elastic constants are set to represent specific alloy systems according to the experimental values, such as InGaN and GeSi.

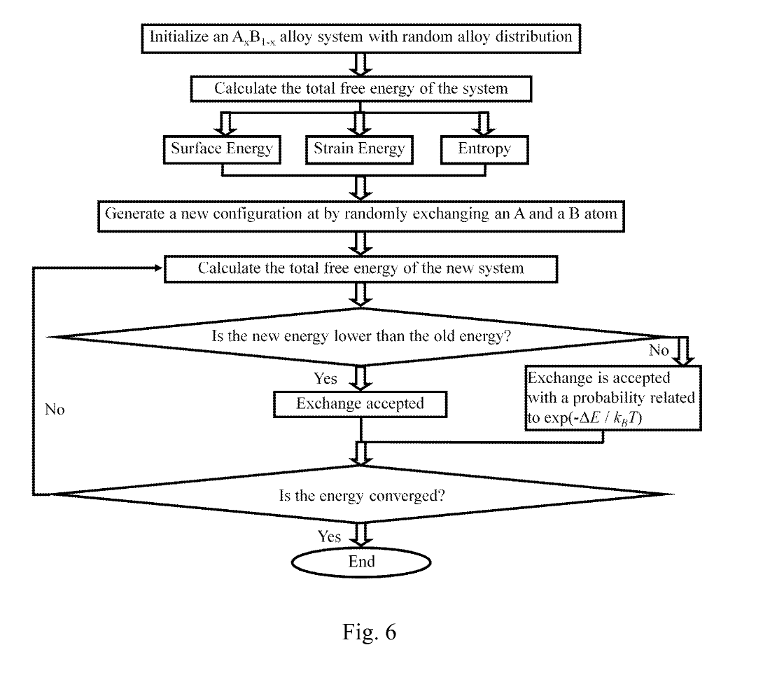

A schematic flow chart of the simulation discussed above is shown in FIG. 6. The simulation relies on the Metropolis Monte Carlo method combined with force-balance approach to minimize the total free energy and find the optimal alloy composition profile. For example, at each time step of atom exchange, the strain energy of the resulting alloy configuration is minimized by the force-balance equation, ∂E/∂u(i)=0, where u is the displacement, to optimize the atomic structure of the given distribution. Thus, if all the atoms in the QD or NW are allowed to exchange their positions, the global equilibrium composition profile is established. In contrast, if the exchanges are confined in the surface regions of the QD or NW, local equilibrium is reached only in the surface regions.

### Example B

### Results of InGaN QDs and NWs on GaN (or Si) Substrates

Alloy phase separation, and specifically the spontaneous core-shell formation during the growth of strained InGaN (or GeSi) QDs or NWs on GaN (or Si) substrates, were simulated by minimizing the Gibbs free energy G:

G=H−TS

where S is the entropy of mixing calculated based on regular solution theory and H is the enthalpy, which is calculated according to the equation:

H=Eₑₗ+Eₛ

where (a) Eₑₗ is the total elastic strain energy including the microscopic strain energy due to the bond distortion in the QDs or NWs and the macroscopic strain energy associated with the lattice mismatch between the QDs or NWs and the substrate (calculated using an atomistic strain model); and (b) Eₛ is the QD or NW surface energy (i.e., the bond-breaking energy at the surface without consideration of surface reconstruction).

Using the experimental elastic constants of InₓGa₁₋ₓN and GexSi₁₋ₓ, simulations produced the interaction parameters of mixing Ω_{InGaN}=−5.16⁻⁴x+0.36 eV/cation and Ω_{InGaN}=−1.83⁻⁵x+0.02 eV/atom, which agree well with previous first principles and valence force field results. The results showed that the interaction parameters depend on alloy composition, rather than being a constant as for the simple regular solution theory. Furthermore, surface energy is implicitly a function of surface composition in the atomistic model, which in principle is more realistic than the previous models that either ignore the surface energy or treat it as a constant; however, the compositional dependence of surface energy was shown not to be a predominant factor in these calculations.

As a qualitative study of the general mechanisms of spontaneous phase separation, a simple two-dimensional (2D) atomistic strain model using a square lattice (see Example A above) was used to calculate the Gibbs free energy of coherently strained alloy QDs or NWs on a substrate, as shown in FIG. 1. The effect of system size was tested for lattices containing up to a few tens of thousands of lattice points. (The number of lattice points in FIG. 1 is schematically reduced for clarity.) This 2D generic model should capture the essential physics of the phase segregation of lattice mismatched alloy structures, because alloys with different lattice structures and materials are expected to behave in qualitatively the same manner. (Incidentally, the 2D projection of the zincblend structure onto the (100) plane is a square lattice.) Similar results are found for the InGaN/GaN and GeSi/Si systems (see Example C below).

In the following Examples B-1, only results of In_{0.3}Ga_{0.7}N QDs and NWs are shown as examples, while some results for GeSi QDs and NWs are provided in Example C.

### Example B-1

### Equilibrium Composition Profiles of Strained Alloy ODs and NWs

The equilibrium composition profiles of strained alloy QDs and NWs were simulated, as shown in FIGS. 1a and b, respectively. InGaN nanostructures ranging from 10 nm to 60 nm in base size were tested. For a given QD or NW shape and fixed alloy composition, results are qualitatively found to be size independent. To reach the equilibrium composition profile, all atoms in the QD or NW were allowed to exchange positions and relax to minimize the total energy using a Metropolis Monte Carlo algorithm as described above. For simplicity, interdiffusion at the interfaces between the substrate and the QD or NW was excluded.

FIG. 1a shows the equilibrium composition profile of a faceted In_{0.3}Ge_{0.7}N alloy QD having a generally pyramidal shape. It is well known that strain relaxes non-uniformly in a Stranski-Krastanov (SK) QD; most relaxation occurs at the apex and least at the corners of the base. Consequently, as shown in FIG. 1a, the highest concentration of In (i.e., the strained component) occurs in the apex region of the QD and the highest concentration of Ga (i.e., the unstrained component) occurs in the corners of the base. This is a well-known phenomenon and the calculations exemplified in the simulation are generally consistent with previous finite element and Monte Carlo calculations.

The strain effect produces phase separation and the large positive enthalpy of mixing for InGaN further favors phase segregation. In fact, a miscibility gap exists for this alloy. The maximum In concentration at the apex is the thermodynamic equilibrium concentration at the particular temperature and precursor concentrations. Due to strain effects, the In concentration decreases continuously from the apex towards the base and the corners of the base in the QD.

The equilibrium In concentration profile in an In_{0.3}Gaₒ₇N NW is shown in FIG. 1b. The base regions of the NW were constrained to be coherent with the substrate lattice while, because of the large height/width aspect ratio, the top regions were fully relaxed. Consequently, nearly all of the In atoms are shown segregated towards the top surface with a slight enrichment in the two top corners.

### Example B-2

### Production of Non-Equilibrium Composition Profiles

The inclusion of kinetic factors that produce non-equilibrium composition profiles, in particular the kinetically controlled phase separation processes that lead to spontaneous core-shell nanostructure formation in semiconductor alloy systems, was studied. Although the thermodynamic equilibrium distribution may be reached in very small nanostructures grown at relatively high temperatures, where diffusion allows redistribution of the alloy components within the entire nanostructures, it is generally not expected for larger nanostructures. This is because bulk diffusion is negligible at typical growth temperatures, having much too high an energy barrier, such as ˜4-5 eV for Ge diffusion in Si and ˜3.4 eV for interdiffusion of In and Ga in InGaN. However, the barriers are greatly reduced at surfaces. For example, diffusion activation energies of ˜0.5-1.0 eV are reported for Si and Ge surface diffusion on Si(100) and ˜0.4 eV for Ga surface diffusion on GaN (0001). The increased diffusion also occurs in the subsurface region. For example, a value of ˜2.5 eV is reported for Ge diffusion in the fourth layer below the Si(100) surface. This allows local equilibrium composition profiles to be established in the surface regions during epitaxial growth. Consequently, the kinetic growth mode, which dictates the surface mass transport and alloy mixing via surface diffusion at the growth front, becomes a key factor in determining the kinetically limited composition profile.

In order to reveal the underlying relationship between the kinetically controlled composition profiles of the epitaxial strained semiconductor alloy QDs or NWs and the growth mode, the effects of two typical growth modes, layer-by-layer versus faceted, on the spontaneous formation of core-shell structures in QDs and NWs, are described in Example B-3.

### Example B-3

### Layer-by-Layer and Faceted Growth of InGaN QDs and NWs

FIG. 2a illustrates a typical Stranski-Krastanov (SK) epitaxial growth process of a strained island or QD.

Where such a process is used to form a nanostructure, in the layer-by-layer growth mode (FIG. 2b), the island growth proceeds in the substrate surface normal direction (indicated by the arrows), with successive nucleation and growth of new surface layers, each on top of the previous complete surface layer. This results in a stepped-mound or wedding cake island structure.

In the faceted growth mode (FIG. 2c), in contrast, the island growth proceeds in the island facet normal direction (indicated by the arrows), with successive nucleation and growth of new facets on top of the previous island facet. This forms a pyramidal structure.

FIG. 3a illustrates the typical vapor-liquid-solid (VLS) growth process for a strained NW Similar to the island or QD growth, the corresponding layer-by-layer and faceted growth modes are shown in FIGS. 3b and 3c, respectively.

While not intending to be limited to any particular theory, it is believed that the local equilibrium composition is reached only in the outmost surface (or facet) layer and the equilibrated surface composition is subsequently frozen upon the growth of the following layer. Such kinetically limited growth leads to the spontaneous formation of core-shell structured QDs (FIGS. 2d and e) and NWs (FIGS. 3d and 3e). The layer-by-layer growth yields structures with cores rich in the unstrained component for both QDs (FIG. 2d, x_{GaN}˜1.0 in the core) and NWs (FIG. 3d, x_{GaN}˜1.0 in the core), while the faceted growth mode yields structures with cores rich in the strained component in both QDs (FIG. 2e, x_{InN}>0.8 in the core) and NWs (FIG. 3d, x_{InN}>0.8 in the core). These growth-mode-controlled alloy composition profiles are distinctively different from the equilibrium composition profiles shown in FIG. 1.

The above results can be qualitatively understood in terms of different strain relaxation mechanisms associated with the different growth modes. In the layer-by-layer growth mode, the growth front is flat. When the atoms are equilibrated within this flat layer, strain relaxation results in a “lateral” phase separation with the strained component (InN) segregating to the outside (i.e., the most relaxed region) and the unstrained component (GaN) to the center of the surface layer. In contrast, in the faceted growth mode, the growth front is inclined at a fixed contact angle with the nominal substrate surface. When the atoms are equilibrated within this inclined facet layer, strain relaxation results in a “vertical” phase separation with InN segregating to the top (i.e., the most relaxed region) and GaN to the bottom of the facet. The segregated surface compositions are successively frozen in as the growth proceeds. Such lateral versus vertical segregation patterns in the layer-by-layer versus faceted modes gives rise to the overall core-shell structures of both QD and NW.

A notable difference in the core-shell structures of QDs is seen, with either a triangle core shape in FIG. 2d or a V-shape in FIG. 2e, from those of NWs, with a straight columnar shape in both FIGS. 3d and 3e. This is because as the QD grows larger in the layer-by-layer mode, the growth font becomes smaller, i.e., fewer atoms are contained within the surface layer. Consequently, fewer In atoms are segregated to the outside. This leads to the triangular core shape in FIG. 2d. Conversely, as the QD grows larger in the faceted mode, the growth font becomes lager, so that more In atoms are segregated to the top. This leads to the V-shaped core in FIG. 2d. The situation for the VLS growth of NWs is different, because the growth fronts in the two growth modes have a constant size, so that the amount of segregation is always the same. This leads to a vertical columnar core-shell structure with uniform width for either growth mode.

A summary of the growth modes, including general descriptions of the concentration profiles of the resulting nanostructures discussed above is provided in Table 1:

TABLE 1

| | STRUC- | GROWTH | STRAINED | UNSTRAINED |
|---|---|---|---|---|
| FIG. | TURE | MODE | COMPONENT | COMPONENT |
| FIG. 1a | QD | N/A* | High [In] at Apex | High [Ga] at Base- |
| | | | | corners |
| FIG. 1b | NW | N/A* | High [In] at Top | High [Ga] at Base |
| | | | | Region |
| FIG. 2d | QD | layer-by- | In-rich side-wall | GaN-rich Core |
| | | layer | surface layers | |
| FIG. 2e | NW | Layer-by- | Columnar InN- | Columnar GaN-rich |
| | | layer | rich shells | Core |
| FIG. 3d | QD | faceted | V-Shapred In-rich | GaN-rich base |
| | | | Core | corners |
| FIG. 3e | NW | faceted | Columnar In-rich | GaN-rich shells |
| | | | Core | |

*N/A—Not Applicable.

### Example B-4

### Effects of Varying the Sub-Surface Diffusion Depth on Composition Profiles

The constraint of equilibration only in the surface layer may be too severe, i.e., enhanced diffusion and hence local equilibration may not be limited only to the top surface (facet) layer, but may extend to several subsurface layers, as suggested by previous calculations and experiments. Thus, the effects of varying the sub-surface diffusion depth on the composition profiles of QDs was also studied.

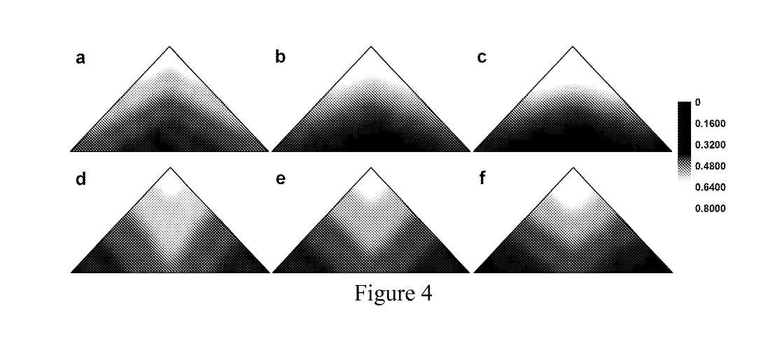

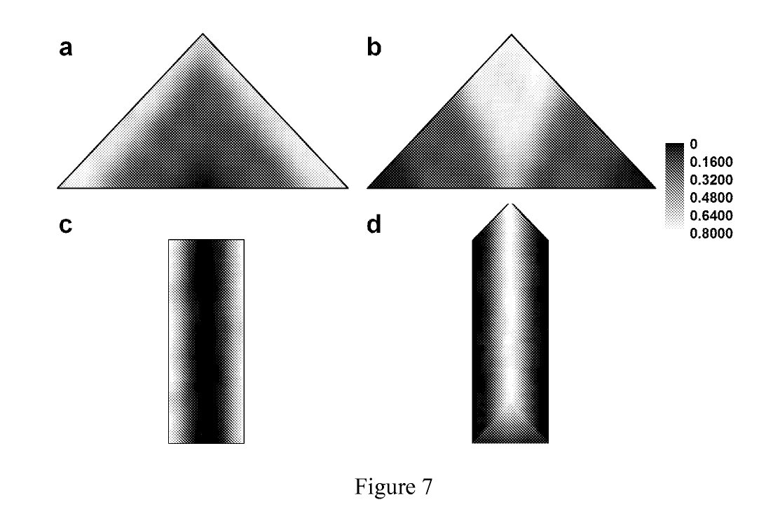

FIG. 4 shows the calculated composition profiles of the InGaN strained alloy QDs grown by the layer-by-layer mode (FIG. 4a-4c) versus the faceted mode (FIGS. 4d and 4c), with the diffusion allowed to depths of 4 layers (FIGS. 4a and 4d), 7 layers (FIGS. 4b and 4e) and 10 layers (FIGS. 4c and 4f), respectively. These results clearly show the impact of diffusion depth on the compositional profile. As expected, increasing the atom mixing depth causes the core-shell structure to gradually disappear and the overall composition profiles obtained from both growth modes to converge towards the equilibrium composition profile (FIG. 1a).

### Example C

### Results of GeSi QDs and NWs on Si substrate

In addition to the In_{0.3}Ga_{0.7}N results discussed above, FIG. 7 shows calculated composition profiles of Ge_{0.3}Si_{0.7} QDs (FIG. 7a-7b) and NWs (FIG. 7c-7d) grown on Si substrates by the two growth modes of layer-by-layer growth versus faceted growth. The representative results of GeSi QDs and NWs parallel those of InGaN QDs and NWs in FIGS. 2 and 3. The results are qualitatively the same, but quantitatively there is a slight difference for the two material systems. For example, the degree of segregation in GeSi is smaller than that in InGaN systems, i.e., the composition profiles vary more slowly in GeSi than in InGaN, because Ge and Si are miscible while the InN and GaN are immiscible.

While in the embodiments described above, structures comprising InₓGa₁₋ₓN and GeₓSi₁₋ₓ are described, the invention is not so limited. Accordingly, embodiments of the invention may include structures comprising other materials, such as other alloy materials known in the art.

### Growth Mode Variation

### Example D

### Surfactants

The growth mode may be varied by the addition of surfactants during growth. Surfactants are known to affect surface thermodynamics, surface kinetics and the growth mode. In addition, surfactants have been shown to directly alter the alloy composition. While not limited to theory, it is believed that the addition of surfactant during epitaxial growth affect the surface diffusion of, for example, In and Ga on an InGaN surface, and, in this way, the growth mode and kinetics, significantly affecting both the size and also the composition of the islands. Preliminary calculations indicate that changes in the In distribution in the islands produce major changes in the performance of these thin layers in the quantum wells constituting the active layers of light emitting diode structures.

### Example D-I

### Addition of Sb

Thin (2-3 nm) InGaN layers, for example, approximately 10 layers, are grown at a temperature of approximately 700° C. Antimony (Sb) obtained from, for example, the decomposition of trimethylantimony is added to the growth composition. The InGaN layers are grown, with a targeted In concentration of about 30%. TMSb flows during growth with Sb flows in the range of 0.5 to 2% of the total group III molar flow rate.

Samples are characterized by examining the effects of Sb on In incorporation and luminescence characteristics, such as wavelength and intensity. Additionally, the island structure is characterized using Atomic Force Microscopy to examine the size of the islands and a related optical technique (NSOM) that allows characterization of the luminescence from individual, nanometer-scale islands. Overall luminescence is measured by the collection of the emission from many islands in a conventional photoluminescence apparatus. In this way, the In redistribution during epitaxial growth, including the effects of surfactant Sb, is characterized.

The growth is carried out by organometallic vapor phase epitaxy. In this process In, Ga, and N are deposited onto the growing surface from the pyrolysis of trimethylindium, trimethylgallium, and ammonia in either a hydrogen or nitrogen (or perhaps a mixture) atmosphere. First, a GaN layer is deposited on a sapphire substrate using well-developed and understood processes at a first temperature. A thin layer of InGaN is subsequently deposited at a second temperature, for example a lower temperature of approximately 700° C.

### Example D-2

### Addition of Bi

Using a similar process as in example D-2, a second set of samples are prepared with bismuth instead of antimony as the surfactant. For example, the use of Bi (from the pyrolysis of trimethylbismuth) as a surfactant is added during the growth of the thin InGaN layers. While not limited by theory, it is believed that the concentrations are less (perhaps by a multiple of 10) than required for Sb in Example D-I. Characterization of the effects of Bi on In content and island size and composition are similar to that described for Example D-I above.

### Device Fabrication

### Example E

### LED Applications

Semiconducting core-shell structures such as quantum dots may be incorporated for use in light emitting diodes. In one embodiment, core shell structures are fabricated with large band-gap shell and small band-gap core configurations to reduce or eliminate surface recombination.

### Example E-1

### InₓGa₁₋ₓN Quantum Dots

InₓGa₁₋ₓN quantum dots are made with a GaN (band-gap of about 3.4 eV) or Ga-rich InₓGa₁₋ₓN shell and In-rich core. Generally x can vary from 0 or about 0 to 1 or about 1. Values for x can also be selected to provide a semiconductor alloy composition capable of absorbing or emitting in the visible spectrum. In some embodiments, an x value greater than 0.5 indicates an In-rich composition, while x<0.5 indicates a Ga-rich composition. Generally, In-rich InₓGa₁₋ₓN includes compositions in which more In is present than Ga. On the other hand, Ga-rich InₓGa₁₋ₓN includes compositions in which more Ga is present than In. In some embodiments, x is the InN mole fraction and can be selected from 0.15 to 0.4 for producing visible light. In these embodiments, an x value of 0.4 or greater would be considered In-rich. As discussed above, the layer-by-layer growth mode yields structures with cores rich in the unstrained component; while the faceted growth mode yields structures with cores rich in the strained component. Accordingly, two options are available for core/shell structure fabrication.

In a first fabrication procedure, GaN (or Ga rich InₓGa₁₋ₓN) is selected as the substrate and a growth mode, for example a growth mode based on the simulations discussed above, is selected. In one embodiment, the faceted growth is selected, e.g., by adding surfactants. In this arrangement, an In-rich InₓGa₁₋ₓN core comprises the strained component while a Ga-rich InₓGa₁₋ₓN shell comprises the unstrained component. In another fabrication procedure, InN (or In rich InxGal_xN) is selected as the substrate and the growth mode, for example a growth mode based on the simulations discussed above, is selected. While InN substrates may not be available, the In-rich InₓGa₁₋ₓN is accessible. In one embodiment, the layer-by-layer growth is selected. In this arrangement, an In-rich shell comprises the strained component while a Ga-rich InₓGa₁₋ₓN core comprises the unstrained component.

### Example E-2

### Additional Applications

Semiconductor structures such as quantum dots made of alloy system such as InGaAs, InGaP and the like can be fabricated following similar procedures as in Example E-1. Additionally, an advantage of the present invention extends beyond alloying. For example, in another embodiment, doping of semiconductor structures is possible. That is, fabrication of core-shell p-n junction structures in radial symmetry, such as a p-type core (shell) and n-type shell (core), can be conducted by selection of appropriate p- and n-type dopants, for example, via selection of appropriate dopants based on size of dopant constituent to affect strain of the structure components relative to the substrate.

In one embodiment, instead of abrupt composition profile transition at the interface of core and shell, the composition profile of a structure of quantum dots or nanowires of the invention can comprise a gradient or continuous profile. For example, changes in or selection of the growth conditions, such as temperature to change diffusion length and alloy mixing depth, can be utilized to cause a continuous growth profile between the core and shell portions of the resulting structure.

Such fabrication methods provide control over the resulting band-gap of the individual structures. Therefore, it is possible to fabricate a range of core-shell structures to cover the whole spectrum of visible light for making white LED and/or attaining high efficiency solar cells.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

It is important to note that various exemplary embodiments described herein are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. The order or sequence of any process or method steps may be varied or re-sequenced according to alternative embodiments. Other substitutions, modifications, changes and omissions may also be made in the design, operating conditions, and arrangement of the various exemplary embodiments without departing from the scope of the present invention.

What is claimed is:

1. A method comprising:
growing a semiconductor alloy structure on a substrate using a growth mode that produces a semiconductor alloy structure having a self-assembled core and shell; and
allowing the structure to form such that one of the core or the shell is strained and the other of the core or the shell is unstrained.

2. The method of claim 1, wherein a lattice structure of a semiconductor component of the semiconductor alloy structure is strained relative to a lattice structure of the substrate.

3. The method of claim 1, wherein the growth mode is a layer-by-layer growth mode.

4. The method of claim 1, wherein the growth mode is a faceted growth mode.

5. The method of claim 1, wherein the semiconductor alloy structure comprises a core that is rich in an unstrained component.

6. The method of claim 1, wherein the semiconductor alloy structure comprises a core that is rich in a strained component.

7. The method of claim 1, wherein the semiconductor alloy structure is a nanostructure.

8. The method of claim 7, wherein the nanostructure is a quantum dot.

9. The method of claim 7, wherein the nanostructure is a nanowire.

10. The method of claim 7, wherein the nanostructure is grown epitaxially.

11. The method of claim 1, wherein the semiconductor alloy structure comprises a spontaneously formed self-assembled core-shell nanostructure.

12. The method of claim 1, wherein the core and shell are formed in a single step.

13. The method of claim 1, wherein the semiconductor alloy structure is a semiconductor quantum dot or a nanowire, wherein the growth mode comprises a faceted growth mode, and wherein the quantum dot or nanowire comprises an indium-rich core portion and a gallium nitride rich surface portion.

14. The method of claim 13, wherein the core portion comprises a V-shaped core.

15. The method of claim 1, wherein the semiconductor alloy structure comprises is a semiconductor quantum dot or nanowire, wherein the growth mode comprises a layer-by-layer growth mode, and wherein the quantum dot or nanowire comprises an indium-rich surface portion and a gallium nitride rich core portion.

16. A self-assembled semiconductor nanostructure comprising a core and a shell, wherein one of the core or the shell is rich in a strained component and the other of the core or the shell is rich in an unstrained component, wherein the nanostructure is a quantum dot or a nanowire.

17. The self-assembled semiconductor nanostructure of claim 17, wherein the core is rich in the strained component.

18. The self-assembled semiconductor nanostructure of claim 18, wherein a compositional profile of at least one of the strained component and unstrained component is substantially continuous between the core and shell.

19. The self-assembled semiconductor nanostructure of claim 17, wherein the nanostructure is part of a light emitting diode structure.

20. A method comprising:
growing at least one semiconductor alloy nanostructures on a substrate, wherein the nanostructure comprises a strained component and an unstrained component; and
controlling a compositional profile during said growing such that a transition between the strained component and an unstrained component is substantially continuous.
